(19) United States
(12) Patent Application Publication
(10) Pub. No.: US 2016/0276959 A1
(43) Pub. Date: Sep. 22, 2016

(54) CONVERTER FOR CONVERTING ENERGY TO BE RECOVERED AND ELECTRICITY GENERATOR

(71) Applicants: COMMISSARIAT À L'ÉNERGIE ATOMIQUE ET AUX ÉNERGIES ALTERNATIVES, Paris (FR); CENTRE NATIONAL DE LA RECHERCHE SCIENTIFIQUE, Paris (FR)

(72) Inventors: Bernard VIALA, Sassenage (FR); Orphee CUGAT, Poisat (FR)

(73) Assignees: COMMISSARIAT A L'ENERGIE ATOMIQUE ET AUX ENERGIES ALTERNATIVES, Paris (FR); CENTRE NATIONAL DE LA RECHERCHE SCIENTIFIQUE, Paris (FR)

(21) Appl. No.: 15/031,988

(22) PCT Filed: Oct. 23, 2014
(86) PCT No.: PCT/FR2014/052704

§ 371 Date: Apr. 25, 2016

(30) Foreign Application Priority Data
Oct. 25, 2013 (FR) 1360430

(51) Int. Cl. H02N 2/18; H01L 41/12

(52) U.S. Cl. CPC H02N 2/18; H01L 41/125

(57) ABSTRACT

A converter for converting a variation in energy to be recovered, the converter including: a transducer layer extending essentially parallel to a reference plane and configured to transform the variation in the energy to be recovered into a mechanical deformation, the transducer layer comprising: a plurality of first blocks made from a magnetostrictive or shape-memory material, the first blocks being delimited in relation to one another by side edges, and regions that do not contain the material of the first block, the regions being inserted between the side edges of the first blocks; and a piezoelectric layer secured to the transducer layer. Each of the first blocks has a preferential axis of deformation parallel to the reference plane.

The invention relates to a converter of a variation of energy to be harvested into a potential difference, the variation of energy to be harvested being a variation of magnetic field or temperature. The invention relates also an electricity generator equipped with this converter.

Known converters of variations of magnetic field or of temperature into a potential difference comprise:

a transducer layer extending essentially parallel to a reference plane and suitable for transforming the variation of energy to be harvested into a mechanical deformation,

a piezoelectric layer having inner and outer faces parallel to this reference plane, the inner face being fixed with no degree of freedom onto most of the transducer layer so as to undergo a mechanical stress exerted by this transducer layer,

a first and a second electrode of electrically conductive material extending essentially parallel to the reference plane along at least one of the faces of the layer of piezoelectric material of the second transducer to show an excess of electrical charges on one of these electrodes in response to the mechanical stress undergone by the layer of piezoelectric material.

Such converters are for example described in the application US2004126620A1. The operation of this type of converter is also presented in the following articles:
Article A1: T. Lafont, J. Delamare, G. A. Lebedev, D. I. Zakharov, B. Viala, O. Cugat, L. Gimeno, N. Galopin, L. Garbuio and O. Geoffroy, “Magnetostrictive-piezoelectric composite structures for energy harvesting”, Journal of micromechanics and microengineering, no 22, 2012,
Article A2: D. Zakharov, G. Lebedev, O. Cugat, J. Delamare, B. Viala, T. Lafont, L. Gimeno and A. Shelyakov, “Thermal energy conversion by coupled shape memory and piezoelectric effects”, PowerMEMS′11, Seoul, Korea, J M M 2012;
Article A3: G. A. LEBEDEV et al, “Thermal energy harvesting using shape memory/piezoelectric composites”, Transducer′11, Beijing, China, Jun. 5-9, 2011.

Prior art is also known from:
PING et al: “High efficiency passive magnetoelectric transducer consisting of PZT and Fe—Ni fork substrate with high Q value”, SENSORS, 2010 IEEE, 2010-11-01, pages 178-181;
FR2973578A1;
PULLAR: “Hexagonal ferrites: A review of the synthesis, properties and applications of hexaferrite ceramics”, Progress in material science, vol. 57, no 7, 2012-03-20, pages 1191-1334;
PING et al: “Effect of adjustable bias voltage on magnetoelectric properties of piezoelectric/magnetostrictive laminate transducer”, Ultrasonic symposium 2012 IEEE, 2012-10-07, pages 2510-2513;
KYUNG et al: “Layout design optimization for magneto-electro-elastic laminate composites for maximized energy conversion under mechanical loading”, Smart materials and structures, vol. 19, no 5, 2010-05-01; pages 55008;
WO2013/042505A1.

The invention aims to increase the efficiency of the converter. The efficiency is here defined as being the quantity of electrical energy produced for a same variation of the energy to be harvested.

The subject thereof is therefore a converter according to claim 1.

The use of a number of first blocks each having a preferential axis of deformation parallel to the reference plane makes it possible to produce a greater deformation of the piezoelectric layer in response to a variation of the energy to be harvested than if a single block were used. Thus, that makes it possible to increase the efficiency of the converter.

In this description, “preferential axis of deformation” denotes the collinear axis to the direction in which the rate of elongation ΔL/L is maximum for a given variation of temperature or of magnetic field and at least two times greater than the rate of elongation measured simultaneously in a direction at right angles parallel to the reference plane, in which ΔL is the amplitude of the deformation of the first block measured in a given direction, and L is the length of the block in this given direction.

The embodiments of this converter can have one or more of the features of the dependent converter claims.

These embodiments of the converter further offer the following advantages:

the use of second blocks whose magnetostriction coefficient is of a sign opposite to that of the first blocks increases the efficiency of the converter;

the use of first blocks of material with shape memory whose preferential axes of deformation intersect on the axis of rotation makes it possible to exert a more uniform mechanical stress on the piezoelectric layer and therefore increase the efficiency of the converter;

the use of a second piezoelectric layer symmetrical to the first piezoelectric layer limits the bending of the converter in a direction at right angles to the reference plane and maintains a planar deformation;

the fact that the blocks of the transducer layer are uniformly distributed about the axis of rotation standardizes the distribution of the stresses exerted on the piezoelectric layer and makes it possible to increase the efficiency of the converter;

the fact that the blocks of the transducer layer are aligned on a same axis makes it possible to effectively transform a translational movement of the sources of energy to be harvested into a potential difference;

the fact that the preferential axes of deformation are parallel to different directions of the reference plane makes it possible to simultaneously stretch and, alternately, shrink the same piezoelectric layer in different directions, which increases the quantity of electricity produced;

the use of a lattice of wires of magnetostrictive material or material with shape memory makes it possible to simply produce a block of magnetostrictive material or material with shape memory having at least one preferential axis of deformation along which the amplitude of the deformation is much greater than in the other directions.

Another subject of the invention is an electricity generator conforming to the independent generator claim.

By simultaneously using a number of first blocks and a number of first sources of energy to be harvested arranged relative to one another so that, in the first position, the mechanical stresses exerted by each of the first blocks are simultaneously maximum, it is possible to increase the quantity of electrical charges generated by a displacement of the claimed converter relative to the case where the converter comprises only a single block of magnetostrictive material or material with shape memory. The second position makes it possible to alternate between the first position in which the mechanical stresses are maximum and the second position in which the mechanical stresses are lesser or of opposite sign. By virtue of this, the potential difference produced by the converter varies as the set of sources of energy to be harvested alternates between the first and second positions. It is therefore possible to produce electrical energy on each displacement of the set relative to the converter. In the absence of such variations of the stress, the production of electrical energy would be impossible.

The embodiments of this generator can comprise one or more of the features of the dependent generator claims.

These embodiments of the generator also offer the following advantages:

the presence of the second sources of magnetic field or of second blocks of magnetostrictive material inserted between the first blocks, makes it possible to increase the amplitude of the variation of the potential difference between the first and second positions which increases the efficiency of the generator,

the use of local sources of heat that can be displaced between the first and second positions makes it possible to generate electrical energy even if the temperature of the sources of heat does not vary.

The invention will be better understood on reading the following description, given purely as a nonlimiting example and with reference to the drawings in which:

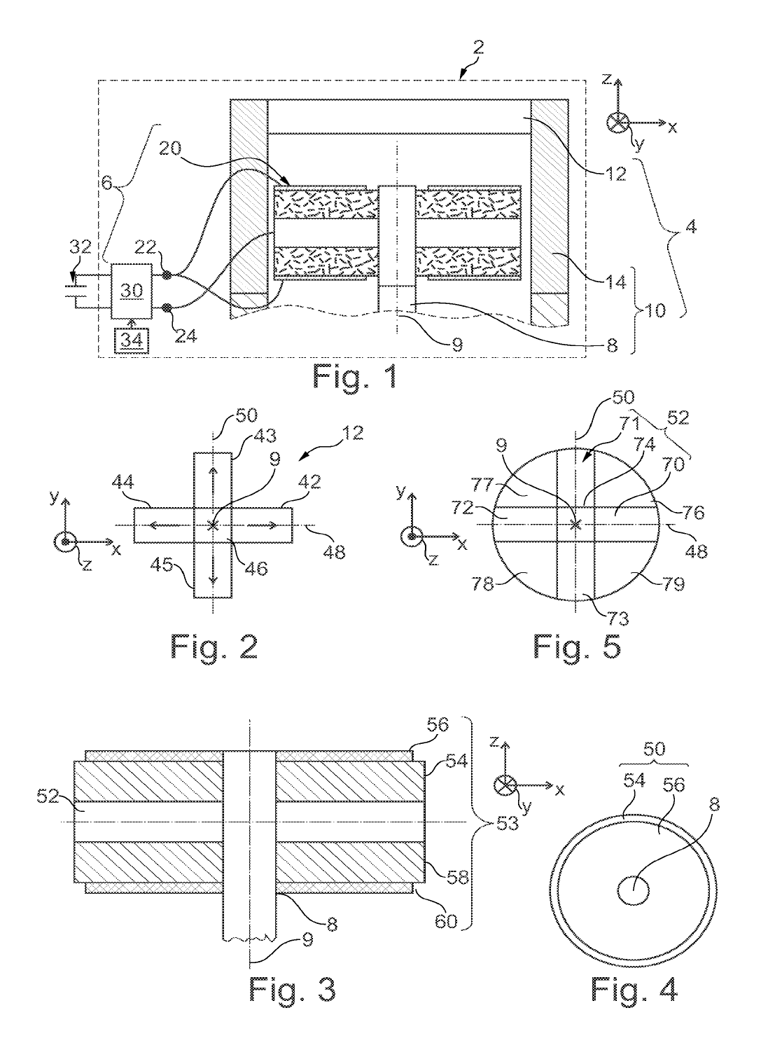

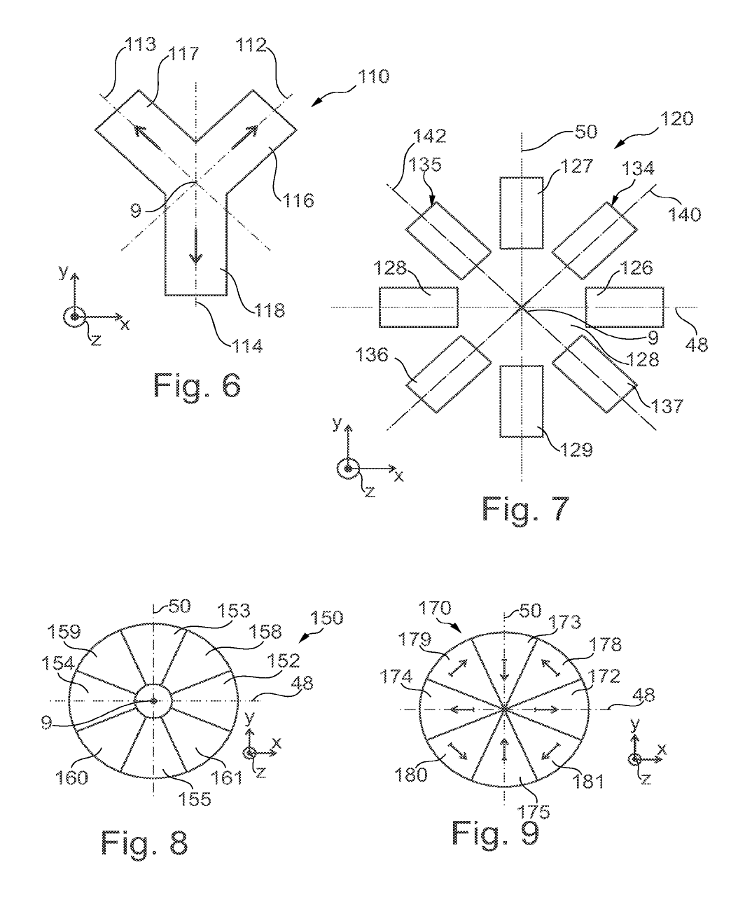

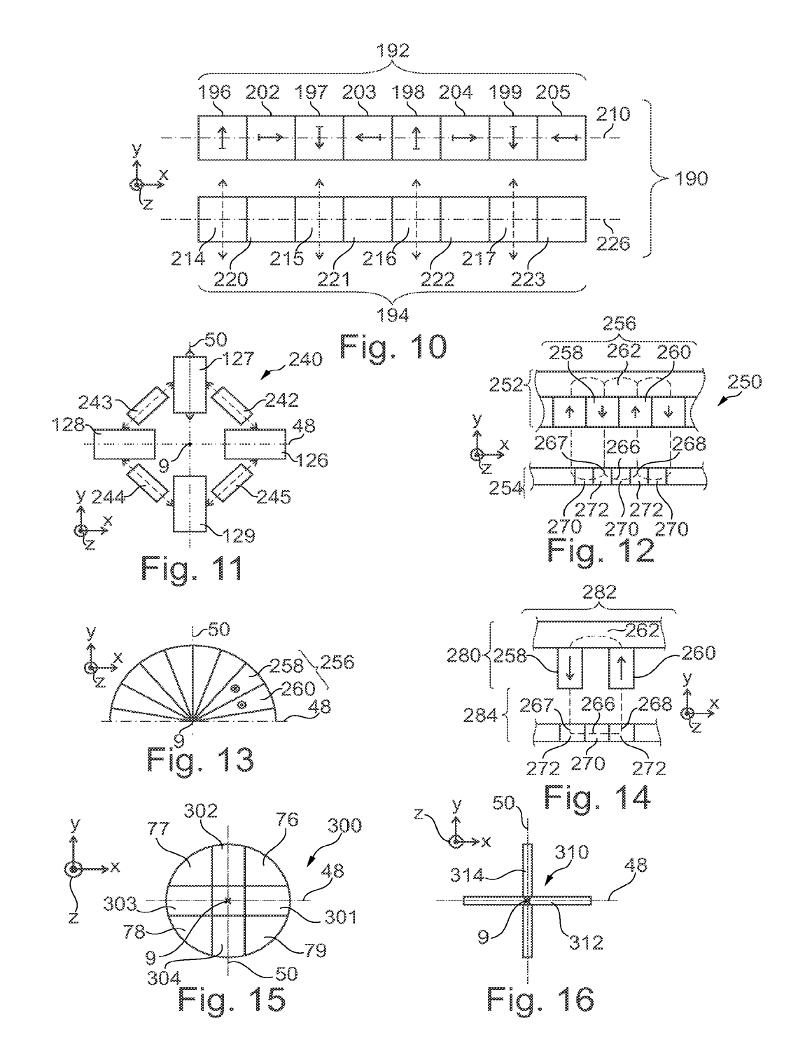

FIG. 1 is a schematic illustration, partially in vertical cross section, of an electricity generator,

FIG. 2 is an illustration, in plan view, of a set of permanent magnets used in the generator of FIG. 1,

FIG. 3 is a schematic illustration, in vertical cross section, of a converter used in the generator of FIG. 1,

FIG. 4 is a schematic illustration, in plan view, of the converter of FIG. 3,

FIG. 5 is a schematic illustration, in plan view, of a transducer layer used in the converter of FIG. 3,

FIGS. 6, 7, 8 and 11 are schematic illustrations, in plan view, of other different embodiments of the transducer layer of FIG. 5;

FIG. 9 is a schematic illustration, in plan view, of an arrangement of a set of permanent magnets likely to be used in place of the arrangement of permanent magnets of FIG. 2 in the particular case of the magnetostrictive layer of FIG. 8;

FIG. 10 is a schematic illustration, in plan view, of another embodiment of the generator of FIG. 1 in the case of a translational movement;

FIG. 12 is a schematic and partial illustration, in vertical cross section, of another embodiment of an electricity generator;

FIG. 13 is a schematic and partial illustration, in plan view, of a set of sources of magnetic field of the generator of FIG. 12;

FIG. 14 is a schematic and partial illustration, in vertical cross-sectional view, of another embodiment of a source of magnetic field of FIG. 13;

FIG. 15 is a schematic illustration, in plan view, of an embodiment of a transducer layer in the case where the variation of energy to be harvested is a variation of temperature;

FIG. 16 is a schematic illustration, in plan view, of an embodiment of a source of energy to be harvested producing a variation of temperature;

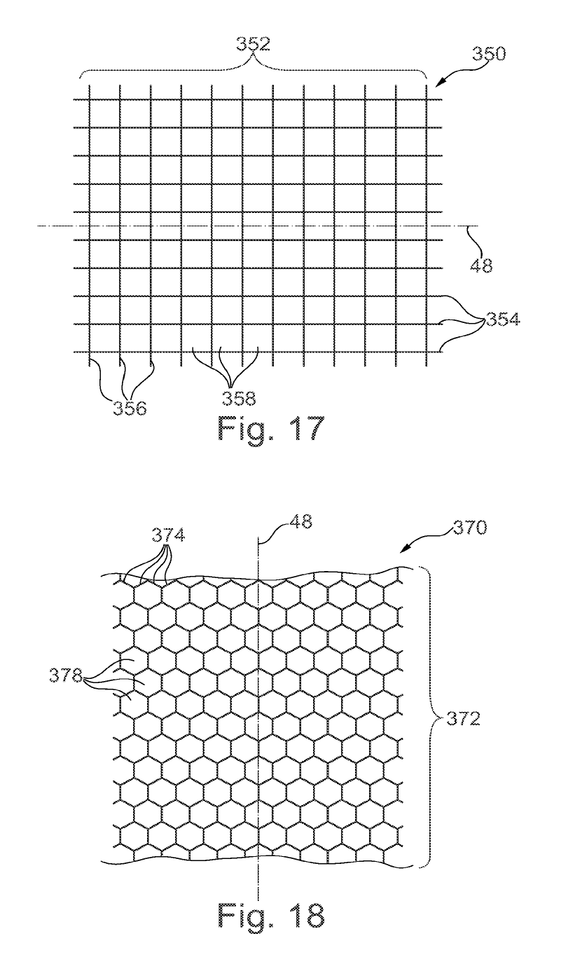

FIGS. 17 and 18 are schematic illustrations of lattice portions used to form blocks of a transducer layer.

In these figures, the same references are used to denote the same elements.

Hereinafter in this description, the features or functions that are well known to those skilled in the art are not described in detail.

FIG. 1 represents an electricity generator 2. This generator 2 comprises:
a source 4 of energy to be harvested, and
a harvester 6 of energy specifically for transforming the energy to be harvested into electrical energy.

Here, the energy to be harvested is a rotation of a magnetic field. For example, the magnetic field revolves around a vertical axis Z of an orthogonal reference frame X, Y, Z. Hereinbelow, each of the figures is oriented relative to this reference frame X, Y, Z.

In this embodiment, the source 4 comprises:
a shaft 8 driven in rotation about a vertical axis 9 and onto which is fixed, with no degree of freedom, a converter 20 of the energy harvester 6, and
a set 12 of uni-axial sources of magnetic field fixed with no degree of freedom onto an immobile frame in proximity to the converter 20.

The shaft 8 is the shaft of an apparatus 10. The apparatus 10 is, for example, a liquid or gas meter and the shaft 8 is the shaft of this apparatus driven in rotation during the metering of the liquid or gas consumed. To simplify, only a part of the apparatus 10 is represented.

The energy harvester 6 comprises:
the converter 20 which converts the revolving magnetic field into a corresponding excess of electrical charges on a connection terminal 22 or 24 relative to the other of these terminals 22, 24.
a circuit 30 for collecting the excess of electrical charges on the terminal 22 or 24 and for transferring these collected electrical charges to an electrical element 32, and
a circuit 34 for controlling the collection circuit 30.

The element 32 is an electricity storage or consumption or transmission element. It comprises one or more electrical components. For example, the element 32 is a capacitor which stores the harvested electrical energy.

The collection circuit 30 and the control circuit 34 are, for example, identical to those described in the application WO 2007/063194 and, preferably, identical to one of those described in the application filed under the number FR 1260047, on Oct. 22, 2012 by the applicant “Commissariat à l'énergie atomique et aux énergies alternatives”. Consequently, these circuits 30 and 34 are not described here in more detail.

FIG. 2 shows the set 12 in more detail. Here, each source of magnetic field of the set 12 corresponds to a uni-axial permanent magnet. “Uni-axial” denotes the fact that each source has just one magnetic moment. In FIG. 2 and subsequent figures, the magnetic moment of each permanent magnet is represented by an arrow. However, the sign with which this magnetic moment is directed is not necessarily important, since a magnetostrictive material is not sensitive to the sign of the field lines. The permanent magnets of the set 12 are fixed relative to one another with no degree of freedom in such a manner that the set 12 simultaneously and permanently has a number of magnetic moments whose orthogonal projections in a horizontal plane are angularly offset relative to one another about the axis 9.

Here, the set 12 comprises four permanent magnets 42 to 45. In FIG. 2, the magnetic moments of the magnets 42 and 44 are parallel to the direction X and the magnetic moments of the magnets 43 and 45 are parallel to the direction Y. More specifically, in the position represented, the magnetic moments of the magnets 42 and 44 are aligned above a horizontal axis 48 parallel to the direction X and intersecting the axis 9. At the same time, the magnetic moments of the magnets 43 and 45 are aligned above a horizontal axis 50 parallel to the direction Y and intersecting the axis 9. The magnets 42 and 44 are symmetrical to one another relative to a vertical plane passing through the axis 50. Likewise, the magnets 43 and 45 are symmetrical to one another relative to a vertical plane passing through the axis 48. Here, the magnets 42 to 45 are arranged at each end of a cross. Furthermore, in this embodiment, the set 12 comprises a central magnet 46 situated on the axis 9 and attached to the north poles of the magnets 42 to 45. The magnetic moment of this magnet 46 is vertical and situated on the axis 9. It reinforces the field lines from the magnets 42 to 45 to the layer 52.

The converter 20 will now be described in more detail with reference to FIGS. 3 to 6. This converter 20 is capable of transforming very slow variations of the energy to be harvested into electricity. “Slow variation” describes variations whose fundamental frequency is less than 1 Hz or 10 Hz. To this end, the converter 20 converts a variation of the amplitude of the magnetic field that is variable in a given direction into a generation of an excess of charges on the terminal 22 and, alternately, on the terminal 24. This conversion is done almost instantaneously such that the voltage between the terminals 22 and 24 varies at the same time and as the amplitude of the variable magnetic field varies in a given direction.

In this embodiment, the converter 20 comprises a transducer layer 52 associated with an electromechanical transducer 53.

The layer 52 extends in a horizontal plane called “reference plane”. It is produced, at least partly, in a magnetostrictive material. Here, “magnetostrictive material” denotes a material for which the absolute maximum value of the magnetostriction coefficient λₛ, at saturation, is greater than 10 ppm (parts per million) and, preferably, greater than 100 or 1000 ppm. The coefficient λₛ is defined by the following relationship: λₛ=ΔL/L, in which:

ΔL is the rate of elongation of the magnetostrictive material along its preferential axis of deformation, and

L is the length of this material in this direction in the absence of external magnetic field.

In this embodiment, the coefficient λₛ is positive. For example, the magnetostrictive material is Terfenol-D or FeSiB or an alloy of FeCo. The layer 52 is described in more detail with reference to FIG. 5.

The electromechanical transducer 53 comprises:

a top horizontal layer 54 of piezoelectric material,

an outer electrode 56,

a bottom horizontal layer 58 of piezoelectric material, and

an outer electrode 60.

In the particular case described here, the layer 52 is also electrically conductive. In these conditions, the layer 52 also fulfils the function of inner electrode for each of the layers 54, 58.

The layer 58 and the electrode 60 are symmetrical images respectively, of the layer 54 and the electrode 56 relative to a horizontal plane situated at mid-height of the layer 52. Consequently, this layer and this electrode are not described in more detail.

The layer 54 extends horizontally over the entire top face of the layer 52. More specifically, it has an inner face glued with no degree of freedom onto this top face of the layer 52. This bottom face covers most and, typically, more than 90% or 98%, of the top face of the layer 52. Here, the layer 54 extends uniformly in each horizontal direction. The layer 54 behaves mechanically as a single block of material.

For example, in this embodiment, the layer 54 is in the form of a horizontal disk passed through at its center by the axis 9.

The layer 54 also comprises a horizontal outer face situated on the side opposite the inner face.

During its operation, the layer 54 generates an excess of electrical charges on the outer face when the layer 52 exerts a mechanical stress on the inner face. This mode of operation is known as mode d₃₁. In this mode of operation, the capacity of the transducer 53 is significant, which improves and facilitates the operation of the converter 20. Typically, this mode of operation of the layer 54 is obtained with a piezoelectric material polarized vertically with the same sign over its entire inner face.

Here, the piezoelectric material has a coupling coefficient k greater than 5% or 10%. This coupling coefficient is defined in the ANSI/IEEE standard 176-1987 “ANSI/IEEE Standard on Piezoelectricity” or in the standards of the EN 50-324 family. More specifically, here, the piezoelectric material used has a piezoelectric coefficient g₃₁ greater than 5×10⁻³ Vm/N and, preferably, greater than 10×10⁻³ Vm/N or 100×10⁻³ Vm/N or 200×10⁻³ Vm/N at 25° C. Here, the piezoelectric material is PZT (lead zirconate titanate) or PMN-PT (lead magnesium niobate-lead titanate), PVDF (polyvinylidene fluoride).

The electrode 56 is produced in an electrically conductive material. Here, electrically conductive material denotes a material whose resistivity at 25° C. is less than 10⁻⁵ Ω·m and preferably less than 10⁻⁶ Ω·m or 10⁻⁷ Ω·m. The electrode 56 is directly deposited on the outer face of the layer 54. Typically, it covers most of this outer face and, preferably, more than 70% or 80% of this outer face. Here, the electrode 56 is produced using a layer in a single piece of electrically conductive material which covers most of the outer face of the layer 54. More specifically, in this embodiment, the electrode 56 forms a ring encircling the shaft 8.

FIG. 5 represents in more detail the structure of the layer 52. The layer 52 is a disk of the same radius as the layer 54. It comprises four blocks 70 to 73 extending along two horizontal axes intersecting on the axis 9. The angle between these horizontal axes is chosen to be equal to the angle that exists between the directions of the magnetic moments of the set 12 to within plus or minus 10° or 5° and, preferably, to within plus or minus 2°. In FIG. 5, the layer 52 is represented in a first particular position in which the blocks 70 to 73 extend, respectively, along mutually orthogonal axes 48 and 50. More specifically, the blocks 70 and 72 are aligned on the axis 48 whereas the blocks 71 and 73 are aligned on the axis 50.

The blocks 70 to 73 are produced in the same magnetostrictive material. Furthermore, each block 70 to 73 has its own preferential axis of deformation. The preferential axis of deformation of a magnetostrictive block is the axis along which the amplitude of its deformation is maximum when it is passed through by field lines parallel to this axis.

For some magnetostrictive material, when the field lines magnetically saturate the magnetostrictive block, the preferential axis of deformation is parallel to these field lines. In this situation, the preferential axis of deformation is imposed by the arrangement of the magnetostrictive block relative to the source of these field lines. When the block of magnetostrictive material is not magnetically saturated, the preferential axis of deformation can also be an intrinsic property of the magnetostrictive block which is due, for example, to the crystalline orientation of the magnetostrictive material and/or to the form factor of the block. Here, “form factor” denotes the ratio of the length to the width of the horizontal rectangle of the smallest surface area inside which the block is contained.

Here, typically, the form factor of each block is strictly greater than 1 or 1.5 or 2 and, in some cases, than 10. The preferential axis of deformation is parallel to the length of the block. Thus, in the embodiments described below, unless indicated otherwise, the preferential axis of deformation of each block is always merged with its longitudinal axis.

Here, each block 70 to 73 is rectangular. They are all situated in the reference plane.

Furthermore, in this embodiment, the layer 52 also comprises a central part 74 which mechanically links the blocks 70 to 73 together. This central part can also be produced in the same magnetostrictive material as the blocks 70 to 73.

Preferably, the blocks 70 to 73 represent most of the horizontal surface area of the layer 52. To this end, the width of each block 70 to 73 is greater than ⅕ and, preferably, greater than ⅓ of the radius of the layer 52. Here, the block 72 is symmetrical to the block 70 relative to the axis 9. Similarly, the block 73 is symmetrical to the block 71 relative to this axis 9. Furthermore, the block 71 is identical to the block 70 except for the fact that it is angularly offset by 90° relative to this block 70.

In the first position, each block 70 to 73 is facing a respective magnet 42 to 45. For example, in this first position, for each block 70 to 73, the surface area of the intersection between the orthogonal projections on the reference plane of this block and of a respective permanent magnet of the set 12 is greater than or equal to more than 50% and, preferentially, more than 80% or 90% of the surface area of this block in this plane. In these conditions, it is said that this block is situated within the orthogonal projection of the permanent magnet. Hereinbelow, this same definition is used to define what is understood by the fact that an element is facing a permanent magnet.

In this embodiment, the layer 52 also comprises four regions 76 to 79 without any magnetostrictive material and inserted between the blocks 70 to 73. The lateral edges of these blocks 70 to 73 are therefore mechanically separated from the lateral edges of the other immediately adjacent blocks by these four regions 76 to 79.

The region 76 is delimited on one side by a lateral edge of the block 70 and on the other side by a lateral edge of the block 71. Its outer periphery is aligned with a vertical edge of the layers 54 and 58. The regions 77, 78 and 79 are identical to the region 76 except that they are angularly offset about the axis 9, respectively by 90°, 180° and 270°. Thus, in this embodiment, each region is essentially in the form of an angular segment whose angle at the vertex is equal to 90°. The thickness of each of these regions 76 to 79 is equal to the thickness of the blocks 70 to 73. In the first position, these regions are situated outside of the orthogonal projections of the permanent magnets of the set 12. An element is considered to be situated outside of the orthogonal projection of a permanent magnet if it is not facing this permanent magnet with the definition given above.

The operation of the generator 2 will now be described. In the first position represented in FIG. 5, the blocks 70 to 73 are passed through by field lines parallel to their respective preferential axis of deformation. In response, the deformation, here the elongation, of the blocks 70 to 73 is maximum. The layer 52 therefore exerts, in this first position, maximum tension stresses on the layers 54 and 58 at the same time along the axes 48 and 50. Thus, in the zones of the outer face of the layers 54 and 58 situated vertically to the blocks 70 to 73, an excess of electrical charges of the same sign is produced. Furthermore, given that the layers 54 and 58 are rigid, the zones of the layers 54 and 58 situated vertically to the regions 76 to 79 are also subjected to a tension stress such that the outer face of these layers 54 and 58 also have zones generating an excess of electrical charges of the same sign. Consequently, in this first position, electrical charges of the same sign are generated over almost all of the outer face of the layers 54 and 58, which increases the potential difference produced by the converter 20.

When the converter 20 makes ⅛ of a turn about the axis 9 from the first position, a second position is reached. In this second position, the blocks 70 to 73 are situated mid-way between two consecutive magnets of the set 12. Furthermore, in this embodiment, the directions of the magnetic moments of the set 12 are angularly offset by 45° relative to the preferential axes of deformation of the blocks 70 to 73. In this second position, it is the regions 76 to 79 which are facing the magnets 42 to 45. Since these regions 76 to 79 have no magnetostrictive material, the blocks 70 to 73 no longer tend to be elongated but, on the contrary, they shrink simultaneously to revert to a rest position. The rest position is the position which would be obtained in the absence of magnetic field. Thus, in this second position, the mechanical stresses exerted by the blocks 70 to 73 on the layers 54 and 58 are minimum.

FIG. 6 represents the arrangement of a transducer layer 110 likely to be used instead of the layer 52 in the converter 20. Here, the number of preferential axes of deformation of the transducer layer is equal to three. More specifically, the layer 110 is identical to the layer 52, except that it comprises three blocks 116 to 118 which extend, respectively, along axes 112 to 114. Here, these axes 112 to 114 are angularly offset relative to one another by 120° such that the angular offset between these axes is uniformly distributed about the axis 9. In this embodiment, the magnetostrictive material of the layer 110 is in the form of a “Y”.

When the layer 110 is used, the set 12 is replaced by a set of permanent magnets arranged relative to one another in order for there to be at least one position in which each of these magnets is facing a respective block of the layer 110. Furthermore, these three permanent magnets are arranged to simultaneously exhibit three horizontal magnetic moments whose mutual angular offsets are identical to the angular offsets that exist between the axes 112 to 114. To simplify FIG. 6, only the orthogonal projection of these three magnetic moments on the reference plane is represented by three bold arrows. With such a set of permanent magnets, the operation of a converter incorporating the layer 110 is identical to the operation described for the converter 20. However, the second position in which the stress exerted by the blocks 116 to 118 is minimum is reached after a rotation of 60° about the axis 9 from the first position represented in FIG. 6.

FIG. 7 represents a transducer layer 120 likely to be used instead of the layer 52 in the converter 20. This layer 120 is identical to the layer 52 except that the blocks 70 to 73 are replaced by blocks 126 to 129. These blocks 126 to 129 are for example identical, respectively, to the blocks 70 to 73. In the first position represented in FIG. 7, the blocks 126 to 129 are therefore facing, respectively, the permanent magnets 42 to 45.

In this embodiment, the regions which separate the blocks 126 to 129 each comprise, respectively, a block 134 to 137 of magnetostrictive material different from that used to produce the blocks 126 to 129. More specifically, the blocks 134 to 137 are produced in a magnetostrictive material whose coefficient A of magnetostriction is of a sign opposite the magnetostrictive material used to produce the blocks 126 to 129. For example, it is, here, SamFeNol which is an alloy of samarium with negative magnetostriction coefficient.

Here, the arrangement of the blocks 134 and 136 is identical to the arrangement of the blocks 126 and 128, except that they are angularly offset by +45° about the axis 9. Similarly, the arrangement of the blocks 135 and 137 is the same as that of the blocks 126 and 128 except that they are angularly offset by −45° about the axis 9. Thus, the blocks 134 and 136 are aligned on a horizontal axis 140 inclined by +45° relative to the axis 48 and the blocks 135 and 137 are aligned on a horizontal axis 142 inclined by −45° relative to the axis 48. The preferential axes of deformation of the blocks 134 and 136 are aligned on the axis 140 whereas the preferential axes of deformation of the blocks 135 and 137 are aligned on the axis 142.

The layer 120 is designed to operate with the set 12 of permanent magnets. The blocks 126 to 129 operate as described with reference to FIGS. 1 to 5. However, in the second position, the blocks 134 to 137 are located facing the magnets 42 to 45. In this second position, the preferential axes of deformation of the blocks 134 to 137 are aligned with the magnetic moments of the set 12. Consequently, the blocks 134 to 137 shrink which exerts compression stresses in the zones of the layers 54 and 58 situated vertically to these blocks 134 to 137. Because of the rigidity of the layers 54 and 58, the shrinking of the blocks 134 to 137 also generates a compression stress in the zones of the layers 54 and 58 situated vertically to the blocks 126 to 129. Thus, in this second position, almost all of the inner surface of the layers 54 and 58 is subjected to a compression stress. That therefore makes it possible to increase the amplitude between the potential differences produced in the first and second positions relative to the embodiment of FIG. 1 and therefore to increase the efficiency of the converter.

FIG. 8 represents, in a first position, a transducer layer 150 likely to be used instead of the layer 52 in the converter 20. This layer 150 is identical to the layer 52 except that the blocks 70 to 73 are replaced by blocks 152 to 155. In the first position, the blocks 152, 154 extend along the axis 48 and the blocks 153, 155 extend along the axis 50. The longitudinal axes of the blocks 152 to 155 are aligned on the axes along which they extend. The block 152 is essentially in the form of an angular segment whose vertex is situated on the axis 9 and the bisecting line of which is merged with the axis 48 in the first position. The angle at the vertex of the block 152 is equal to 45°. Here, the vertex of this angular segment is eliminated to leave a passage for the axis 8. The blocks 153 to 155 are identical to the block 152 except that they are angularly offset about the axis 9 relative to the block 52 by, respectively, 90°, 180° and 270°. With this choice of the value of the angle at the vertex of the block 152, the regions 158 to 161 without any magnetostrictive material are also angular segments of the same form as the block 152 but angularly offset about the axis 9, respectively, by 45°, 135°, 225° and 315° relative to the position of the angular segment of the block 152.

FIG. 9 represents a set 170 of permanent magnets intended to replace the set 12 when the layer 52 is replaced by the layer 150. The set 170 is identical to the set 12 except that the permanent magnets 42 to 45 are replaced, respectively, by permanent magnets 172 to 175. The magnets 172 to 175 each have the same form as the blocks 152 to 155 and are arranged relative to one another as described for the blocks 152 to 155. However, the vertex of the angular segment of each magnet has not been eliminated to leave a passage for the axis 8. Thus, in the first position, each block 152 to 155 is facing a respective magnet 172 to 175. The directions of the magnetic moments of the magnets 172 and 174 are aligned on the axis 48. Conversely, the directions of the magnetic moments of the magnets 173 and 175 are aligned on the axis 50.

Facing the regions 158 to 161, in the first position, the set 170 comprises additional permanent magnets, respectively 178 to 181. Each of these magnets 178 to 181 has the same form as the magnet 172. These magnets 178 to 181 are angularly offset about the axis 9 by, respectively, 45°, 135°, 225° and 315° relative to the position of the magnet 172. Thus, after a rotation of 45° of the layer 150 to reach a second position, each block 152 to 155 is located facing a respective magnet 178 to 181.

The direction of the magnetic moments of the magnets 178 to 181 is chosen so that the magnetic field lines that they generate within the blocks 152 to 155 in the second position are turned by 90°, in a horizontal plane, relative to the magnetic field lines that the magnets 172 to 175 generate within these same blocks but in the first position. For that, the direction of the magnetic moment of each magnet 178 to 181 is at right angles to the bisecting line of the angular segment occupied by this magnet and whose angle at the vertex is situated on the axis 9.

During the operation of the layer 150, in the first position, the blocks 152 to 155 are elongated radially and simultaneously exert a tension stress on the inner face of the layers 54 and 58 as described for the layer 52. In the second position, the blocks 152 to 155 are this time facing the magnets 178 to 181. In this second position, the magnetic field lines which pass through the blocks 152 to 155 are at right angles to the longitudinal axes of these blocks. Consequently, in the second position, each block 152 to 155 is elongated in the direction of the field lines which pass through it which correspond to a shrinkage in the horizontal direction at right angles to its longitudinal axis. Thus, the blocks 152 to 155 exert a radial compression stress on the layers 54 and 58. As in the embodiment of FIG. 7, that therefore makes it possible to increase the amplitude between the potential differences produced in the first and second positions.

The embodiments described hitherto have been described in the particular case where the converter rotates relative to the set of permanent magnets. However, everything that has been described in this particular context applies equally to the case where the set of permanent magnets is displaced in translation relative to the converter parallel to the reference plane. To switch from one embodiment to the other, it is sufficient to “unwind” the structures described in the case of a rotary movement to obtain the corresponding embodiment in the case of a translational movement.

For example, FIG. 10 represents a generator 190 corresponding to the embodiment of FIGS. 8 and 9 but with a translational movement. To simplify FIG. 10, only the main elements which differ from the generator 2 are represented. More specifically, in the generator 190, the set 12 is replaced by a set 192 of permanent magnets and the layer 52 is replaced by a layer 194. The layer 194 is inserted between two layers of piezoelectric materials similar to the layers 54 and 58. In FIG. 10, the set 192 and the layer 194 are represented in plan view and alongside one another. In reality, the set 192 and the layer 194 are superposed vertically one on top of the other.

The set 192 comprises four permanent magnets 196 to 199 and four permanent magnets 202 to 205. All these magnets are placed on a same axis 210 parallel to the direction X. The magnets 202 to 204 are inserted between, respectively, the magnets 196, 197, the magnets 197, 198 and the magnets 198, 199. The magnet 205 is attached, on the right, to the magnet 199. The magnets 196 to 199 each have a uni-axial magnetic moment parallel to the direction Y. The magnets 202 to 205 each have a uni-axial magnetic moment parallel to the direction X. All the magnets have the same width in the direction X.

The layer 194 comprises four blocks 214 to 217 in the same magnetostrictive material separated by four regions 220 to 223 without any magnetostrictive material. These blocks and regions are all aligned on an axis 226 parallel to the direction X. More specifically, the regions 220 to 222 are inserted between, respectively, the blocks 214, 215, the blocks 215, 216 and the blocks 216, 217. The region 223 is here attached to the right of the block 223. This region 223 can also be omitted. The preferential axes of deformation of the blocks 214 to 217 are parallel to the direction Y.

The set 192 and the layer 194 can be displaced relative to one another between a first position, represented in FIG. 10, and a second position. In the second position, the layer 194 is offset by one pitch to the left, in the direction X, relative to the first position. Here, this pitch is equal to the width of a permanent magnet of the set 192.

In the first position, the blocks 214 to 217 are situated facing the magnets 196 to 199 and the regions 220 to 223 are situated facing the magnets 202 to 205. In the second position, it is the regions 220 to 223 which are situated facing the magnets 196 to 199 and the blocks 215 to 217 which are situated facing the magnets 202 to 204. In this example, in the second position, the block 214 is not facing any element.

In the arrangement described, the magnets 196 to 199 correspond functionally to the magnets 172 to 175 and the magnets 202 to 205 correspond functionally to the magnets 178 to 181. Similarly, the blocks 214 to 217 correspond functionally to the blocks 152 to 155 and the regions 220 to 223 correspond functionally to the regions 158 to 155. Thus, the operation of the generator 190 is deduced from the operation of the layer 150 with the set 170 except that here, the electricity generation is provoked by a translational displacement in the direction X of the layer 194 relative to the set 192 and not by a rotational movement.

FIG. 11 represents a transducer layer 240 intended to replace the layer 120. This layer 240 is identical to the layer 120 except that the blocks 134 to 137 are replaced by blocks of magnetostrictive material, respectively 242 to 245. The blocks 242 to 245 are produced in a magnetostrictive material whose magnetostriction coefficient is of the same sign as that of the blocks 126 to 129. Typically, the blocks 242 to 245 are produced in the same magnetostrictive material as the blocks 126 to 129. Here, each block 242 to 245 is formed so as to have a preferential axis of deformation merged with its longitudinal axis. The blocks 242 and 244 are arranged, respectively, between the blocks 126, 127 and the blocks 128, 129 such that their preferential axes of deformation are at right angles to within plus or minus 10° or 5° to the axis 48 in the second position. Similarly, the blocks 243 and 245 are arranged between, respectively, the blocks 127, 128 and the blocks 129, 126 such that their preferential axes of deformation are at right angles to within plus or minus 10° or 5° to the axis 50 in the second position. In these conditions, the blocks 242 to 245 fulfill the same function as the blocks 134 to 137. In effect, in the second position, each of these blocks 242 to 245 exerts a compression stress on the layers 54 and 58 because the field lines pass through these blocks 242 to 245 at right angles to their preferential axis of deformation in the second position.

FIGS. 12 and 13 represent a generator 250 identical to the generator 2 except that:

the set 12 is replaced by a set 252 of sources of magnetic field, and

the layer 52 is replaced by a transducer layer 254.

To simplify FIG. 12, only the different elements are represented. In FIG. 13, only half of the set 252 is illustrated.

In the set 252, each source of magnetic field is produced using two permanent magnets and not just one. These sources are angularly offset relative to one another in a horizontal plane to be uniformly distributed about the axis 9. Apart from this difference, the sources are identical to one another. Thus, only one source 256 of the set 252 will now be described in detail. The source 256 comprises two uni-axial permanent magnets 258, 260. The magnetic moments of these two magnets 258, 260 are vertical and of opposite signs. In this embodiment, they are attached to one another. On the side opposite the layer 254, the source 256 comprises a yoke portion 262 of magnetic material which magnetically connects the two top poles of the magnets 258 and 260. In these conditions, the source 256 generates a magnetic field which loops back, on the top side, via the yoke 262 and, on the bottom side, via the layer 254. Within the layer 254, this magnetic field extends along field lines 266 parallel to the reference plane and, at each end of these lines 266, along the field lines 267 and 268 parallel to the direction Z to within plus or minus 20° or 10°.

Preferably, the magnets 258 and 260 are common to the sources of the set 252 situated immediately upstream and downstream of the source 256.

In the first position represented in FIG. 12, the layer 254 comprises, as in the preceding embodiments, blocks 270 of magnetostrictive material situated facing each source of the set 252. Here, the orthogonal projection of the source 256 on the reference plane comprises the orthogonal projection of the magnets 258, 260. Furthermore, given that the magnets 258, 260 are common to two immediately adjacent sources, these orthogonal projections of these two sources straddle one another. In this embodiment, in addition to facing the source 256 in the first position, the block 270 is only situated at the location of the field lines 266. Preferably, the field lines 266 magnetically saturate the block 270. Thus, in this embodiment, the preferential axis of deformation of the block 270 is parallel to the field lines 266 in the first position. This preferential axis of deformation is therefore at right angles to a radius of the layer 250 and therefore parallel to the direction X in the position represented in FIG. 12. Thus, in this embodiment, the preferential axis of deformation is not parallel to the longitudinal axis of the block 270.

Regions 272 are inserted between each pair of adjacent blocks 270. These regions 270 for example have no magnetostrictive material. Through their arrangement relative to the blocks 270, the regions 272 are essentially passed through by vertical field lines 267, 268 in the first position. Thus, in the first position, the blocks 270 are essentially passed through by the horizontal field lines 266 parallel to their preferential axis of deformation. The blocks 270 are therefore stretched horizontally. Thus, in the first position, the layers 54 and 58 are only subjected to tension stresses exerted by the blocks 270.

The second position is reached after a rotation about the axis 9 by an angle equal to the angle at the vertex of a block 270. In the second position, it is the regions 272 which are passed through by the horizontal field lines 266 whereas the blocks 270 are passed through by the vertical field lines 267, 268. In this position, all the blocks 270 are retracted horizontally. Thus, all the blocks 270 simultaneously exert compression stresses on the layers 54 and 58.

FIG. 14 represents a set 280 of sources 282 of magnetic field likely to replace the set 252 of the generator 250. Each source 282 is identical to the source 256 except that the magnets 258, 260 are spaced apart horizontally from one another by a distance, for example, greater than d/2 or d, where d is the width of the magnet 258 in a horizontal plane. When the set 280 is used, the layer 254 is replaced by a layer 284. The layer 284 is identical to the layer 254 except that the dimensions of the blocks 270 and of the regions 272 are adjusted to take account of the space which exists between the magnets 258 and 260. The operation of the set 280 with the layer 284 is the same as that described with reference to FIGS. 12 and 13. It will however be noted that, in this embodiment, the orthogonal projection of the source 282 on the reference plane comprises the orthogonal projection of the magnets 258, 260 and of the space situated between these two magnets.

FIG. 15 represents a transducer layer 300 intended to replace the layer 52 when the variation of energy to be harvested is a variation of temperature. The layer 300 is here identical to the layer 52 except that the blocks 70 to 73 are replaced, respectively, by blocks 301 to 304. In this embodiment, the blocks 301 to 304 are identical to the blocks 70 to 73 except that they are produced in a material with shape memory. The preferential axis of deformation of the blocks 301 and 303 is parallel, in the first position represented in FIG. 15, to the axis 48. In this first position, the preferential axis of deformation of the blocks 302 and 304 is parallel to the axis 50. As in the case of the blocks of magnetostrictive material, the preferential axis of deformation is, here, the axis along which the amplitude of the deformation is maximum in response to a given variation of temperature. Furthermore, as for the blocks of magnetostrictive material, when the block of material with shape memory contracts along its preferential axis of deformation, it simultaneously elongates along a horizontal axis at right angles. Each block 301 to 304 is here configured for, in response to an increase in the external temperature, it to contract along its preferential axis of deformation and, simultaneously, elongate along another axis at right angles. However, in the case of the materials with shape memory, the direction of the preferential axis of deformation is an intrinsic characteristic of the block configured during its production. Thus, the direction of the preferential axis of deformation of the blocks 301 to 304 does not depend on their relative position in relation to the source of energy to be harvested. Here, the material with shape memory has an elongation rate, along its preferential axis of deformation, at least greater than 0.5% or 1% in response to a variation of temperature of 10° or of 20° C. For more information on the materials with shape memory that can be used in such a converter, reference can be made to articles A2 and A3.

In the case where the layer 300 is used in the converter, the set 12 of permanent magnets is replaced by a set 310 of sources of heat represented in FIG. 16. The set 310 comprises two sources 312 and 314 of heat. The sources 312 and 314 extend only along, respectively, axes 48 and 50 so as to essentially heat the blocks facing these axes while heating much less the regions which are not facing these axes. For example, in this first position, for each block 301 to 304, the surface area of the intersection between the orthogonal projections on the reference plane of this block and of the source facing the set 310 is greater than or equal to more than 30% or 50% and, preferably, more than 80% or 90% of the surface area of this block in this plane. As an illustration, the sources 312 and 314 are pipes that are passed through by a heat transfer fluid. The sources 312 and 314 can also be filaments or heating resistors. In this embodiment, since the layer 300 rotates relative to the set 310, the temperature of the sources 312 and 314 is, for example, constant. The blocks 301 to 304 are heated when they are located facing the sources 312 and 314 and cool down when they are facing the regions 76 to 79. The operation of the generator equipped with the layer 300 and the set 310 is deduced from the explanations given with reference to FIGS. 2 to 4.

Many other embodiments are possible. For example, the electrode 56 does not need to be formed from a single block of material. As a variant, the electrode 56 comprises a number of conductive pads distributed over the outer face of the layer 54 and separated mechanically from one another by trenches filled with an electrically insulating material, electrical conductors connecting these different pads in series.

As a variant, an inner electrode of electrically conductive material is inserted between the layers 52 and 54. That proves necessary in any embodiment in which the transducer layer is produced in a material which is not electrically conductive.

The outer electrodes are not necessarily directly fixed onto the layer of piezoelectric material. For example, they can be separated from this layer by a thin intermediate layer, for example having a thickness less than 1/100^{th} or 1/1000^{th} of the thickness of the piezoelectric layer. They can also be slightly mobile relative to the layer of piezoelectric material.

Hitherto, only the mode d₃₁ of the layer of piezoelectric material has been used. As a variant, it is possible to use a layer of piezoelectric material operating according to the mode d₃₃. For example, the piezoelectric transducer is produced as described with reference to FIG. 3 of the article A1 cited previously. In other words, a layer of horizontally polarized piezoelectric material is used. In the first position, the direction or directions of polarization are parallel to the preferential axes of deformation of the blocks. The electrodes used are then formed by one or more combs. Each comb is composed of a number of fingers of electrically conductive material each extending parallel to a direction at right angles to the direction of polarization of the piezoelectric layer. Each comb of an electrode is interlaced or “interdigitated” with a corresponding comb of the other electrode to form a configuration known as “Interdigitated combs”. In the article A1, each electrode comprises two pairs of combs arranged, respectively, on the outer and inner faces of the layer of piezoelectric material. However, when the layer of piezoelectric material operates in mode d₃₃, all the electrodes can be placed on a same face of the layer of piezoelectric material. It can be the inner or outer face of the layer of piezoelectric material. It is also possible to place a single comb on each face of the piezoelectric layer, these combs then being offset relative to one another in the direction of polarization of the piezoelectric layer.

The layer 54 of piezoelectric material can take other forms. For example, advantageously, it can also be shaped in ellipsoid form rather than disk form. The horizontal section of this layer 54 can also, as a variant, be square or rectangular or be a polygon with more than five vertices.

Nor is the piezoelectric layer necessarily made of a single block. For example, it can also be produced by attaching a number of blocks of piezoelectric material alongside one another. However, even in this case, the different blocks of the piezoelectric layer are fixed to one another with no degree of freedom so as to behave mechanically as a single block of material. Typically, all the blocks of piezoelectric material are polarized with the same sign.

Piezoelectric materials other than PZT or PMN-PT can be used. For example, the piezoelectric material can be PVDF (polyvinylidene fluoride). In this case, the thickness of the layer 54 is less than 300 μm and, preferably, less than 100 μm or 30 μm or 20 μm. Generally, the thickness “e” of this layer is less than 10 μm. The choice of a thin layer of PVDF makes it possible to increase the efficiency of the converter 20. The piezoelectric material can also be a piezoelectric foam such as one of those described in the following article:

Imran Patel, “Ceramic based intelligent piezoelectric energy harvesting device”, Intechopen, 6 Sep. 2011.

Each permanent magnet can be produced in a single block of material. Each permanent magnet can also be composed of a stack of a number of magnetized plates one on top of the other, each plate of the stack having a magnetic moment parallel to that of the other plates of this stack. The sign of the magnetic moment of one plate relative to that of the other plates of the same stack is unimportant because the magnetostrictive material is only sensitive to the direction of the magnetic moment and not to its sign.

The set 12 can be produced without using permanent magnets. For example it can be produced by using coils passed through by a current.

The permanent magnets of the set 12 can be arranged in a plane which is not necessarily parallel to the reference plane. In another variant, the directions of the magnetic moments of the sources of the set are not all coplanar.

The magnet 46 can be omitted.

The directions of the magnetic moments can be modified. For example, in the embodiment of FIG. 10, the directions of the magnetic moments of all the magnets 196 to 199 and 202 to 205 are turned by 45° to the right. An angular offset of 90° between the magnetic moments of two immediately consecutive magnets is thus retained. The preferential axis of deformation of the blocks 214 to 217 is then also turned by 45°. The operation of this variant remains the same as that described with reference to FIG. 10. Similarly, the directions of the magnetic moments and of the axes of deformation of the set 170 can also be turned. Similarly, the directions of the magnetic moments of the magnets in the other embodiments can be modified provided that, in the first position, the mechanical stress exerted on the zones of the piezoelectric layers vertically to the blocks are all of the same sign. These modifications of the directions of the magnetic moments may or may not be accompanied by corresponding modifications of the directions of the preferential axes of deformation of the blocks.

The number of blocks of magnetostrictive material and the number of sources of magnetic field can be greater than 4, 8 or 12. This number can be very great notably in the case of a linear displacement as described with reference to FIG. 10. Preferably, if the displacement between the first and second positions is done by rotation, then the number of blocks is less than 12. However, if the number of blocks of the transducer layer is strictly greater than 12, then it is possible to provide, in each region separating the different blocks of the transducer layer, a mechanism limiting or eliminating the magnetic couplings likely to exist between its different blocks.

The different blocks of the transducer layer do not necessarily extend in the same plane. In this case, the reference plane is the median plane to the various planes in which these different blocks extend and the orthogonal projection of a block is considered on this reference plane in order to know if the latter is situated within the orthogonal projection of a uni-axial source of magnetic field.

If a magnetostrictive material with negative magnetostriction coefficient is used in place of a magnetostrictive material with positive magnetostriction coefficient, in the first position, the sign of the mechanical stresses exerted by the blocks is reversed relative to that which was described in the case of a magnetostrictive material with positive magnetostriction coefficient.

The different blocks of magnetostrictive material having magnetostriction coefficients of the same sign are not necessarily produced in the same magnetostrictive material.

The magnetostrictive material can also be replaced by an alloy with magnetic shape memory such as NiMnGa, that is to say a material which works as described for the preceding materials with shape memory except that the deformation is triggered by a variation of the magnetic field and not by a variation of temperature.

The different embodiments previously described can be combined. For example, the set 170 can be used with the layer 120 or 240. In accordance with the teaching of the embodiment of FIG. 7, the regions 220 to 223 can be replaced by blocks of magnetostrictive material whose magnetostriction coefficients are negative and whose preferential axes of deformation are parallel to those of the blocks 214 to 217.

The different variants described above in the particular case of blocks of magnetostrictive material can be adapted to the case of the blocks of material with shape memory. Furthermore, in the case of the blocks of material with shape memory, it is possible to vary the temperature of these blocks without displacing the layer 300 relative to local sources of heat. For that, for example, the set 310 is replaced by a source of heat capable of heating up, similarly and simultaneously, all of the blocks 301 to 304 and whose temperature varies over time.

Each block of the transducer layer is not necessarily a solid block. As a variant, this block is holed. For example, the block is formed by a lattice of wires extending in the reference plane. The wires of the lattice are produced:

either in a magnetostrictive material to form a block of magnetostrictive material,

or in a material with shape memory to form a block of material with shape memory.

Each lattice comprises more than 10 or 50 or so wires which are interwoven. Each wire has a form factor greater than 10 or 30 and, generally, greater than 50. Often, the longest wires extend mainly in a direction parallel to the preferential axis of deformation of this block. For example, the longest wires are at least two times and, preferably, ten times, longer than the other wires of the lattice which extend in other directions.

FIG. 17 represents a block 350 of material with shape memory likely to replace any one of the blocks 301 to 304 of the transducer layer 300. In FIG. 17, the block 350 is represented in a position in which it extends mainly along the axis 48. The block 350 is formed by a lattice 352 of wires of material with shape memory. In the particular case represented, the lattice 352 comprises only rectilinear wires 354 which extend parallel to the axis 48 and rectilinear wires 356 which extend only at right angles to the axis 48. The interweaving of the wires 354 and 356 therefore forms meshes 358 of rectangular horizontal section. In the example represented, the section of the meshes 358 is square. Here, the wires 354 and 356 are structurally identical except that the wires 354 are, typically, two or five times longer than the wires 356. In FIG. 17, this scale factor between the lengths of the wires 354 and 356 is not observed to simplify the illustration. On each crossing between the wires, these wires are fixed mechanically to one another with no degree of freedom.

Many forms of meshes are possible for the lattice. For example, FIG. 18 represents a block 370 formed by a lattice 372 in which wires 374 are interwoven to form meshes 378 whose horizontal section is hexagonal or in honeycomb form. In this figure, the wavy lines indicate that only a part of the block has been represented. In the lattice 372, the wires 374 extend mainly in a direction parallel to the preferential axis of deformation of the block 370. These wires 374 overlap or are merged with one another at edges of each mesh 378 parallel to the axis 48. Here, all the wires 374 have, for example, the same length and there are no other wires extending in a direction at right angles to the axis 48. In other embodiments, the horizontal section of the meshes is a rhombus.

In the preceding examples, the meshes 358 and 378 have form factors equal to one. In this case, the mesh does not in itself have any preferred direction of deformation and it is therefore the form factor of the block which reveals a preferential axis of deformation. Here, the “form factor” of a mesh is the ratio of the length to the width of the horizontal rectangle of smallest surface area within which the mesh is entirely contained. In the preferred embodiments, the form factor of the meshes is greater than 1.5 or 2 or 5. For example, the meshes are rectangular. In the latter case where the meshes are longer than they are wide, each mesh has in itself a preferred direction of deformation in the direction in which the mesh is longest. Preferably, the preferred direction of deformation of the mesh is parallel to the preferential axis of deformation of the block. Such a configuration makes it possible to increase the amplitude of the deformation of the block along its preferential axis of deformation. If the block has a form factor equal to one, the presence of meshes having parallel preferred directions of deformation makes it possible to create a preferential axis of deformation parallel to these preferred directions. Thus, the use of a lattice with meshes with a form factor strictly greater than one is an exemplary embodiment which makes it possible to obtain a block having a preferential axis of deformation without in any way this block having a form factor strictly greater than one.

The wires do not necessarily have a circular cross section. This cross section can also be rectangular. In the latter case, these wires are thin strips of magnetostrictive material or material with shape memory.

It is not necessary for the longest wires to extend parallel to the preferential axis of deformation. For example, in another embodiment, first rectilinear wires are inclined by +45° relative to the axis 48 and second rectilinear wires are inclined by −45° relative to the axis 48. These first and second wires all have the same length or, as a variant, all have different lengths. In this case, the preferential axis of deformation remains parallel to the axis 48 although none of the first and second wires extend parallel to this axis.

All that has been described for lattices with wires of material with shape memory applies equally to lattices with wires of magnetostrictive material.

It is also possible to insert a piezoelectric layer between two transducer layers. For example, a number of converters 20 centered on the axis 9 can be stacked vertically one on top of the other.

The converter can also be mounted at the end of the shaft 8 such that the piezoelectric and transducer layers are not passed through by this shaft 8.

The relative movement of the set 12 relative to the converter 20 can also be obtained by fixing the assembly 12 with no degree of freedom onto the end of the axis 8 and by fixing the converter 20 onto the immobile frame 14.

The apparatus 10 can be a mechanical rolling bearing. In this case, the axis 8 is the axis of this rolling bearing and the frame 14 is the frame of the rolling bearing.

1-15. (canceled)

16. A converter of a variation of energy to be harvested into a potential difference between two electrical terminals, the variation of energy to be harvested being a variation of magnetic field or of temperature, the converter comprising:
a transducer layer extending substantially parallel to a reference plane and configured to transform the variation of energy to be harvested into a mechanical deformation, this transducer layer comprising:
a number of first blocks of magnetostrictive material or material with shape memory, these first blocks being delimited from one another by lateral edges; and
regions without any first block, these regions being inserted between the lateral edges of these first blocks;
a piezoelectric layer formed from a single block of piezoelectric material or from a number of blocks of piezoelectric material attached alongside one another and fixed to one another with no degree of freedom to behave mechanically as a single block of material, this piezoelectric layer having inner and outer faces parallel to the reference plane, the inner face being fixed with no degree of freedom onto most of the transducer layer to undergo a mechanical stress exerted by this transducer layer;
a first and a second electrode of electrically conductive material extending substantially parallel to the reference plane along at least one of the faces of the piezoelectric layer to show an excess of electrical charges on one of these electrodes in response to the mechanical stress undergone by the piezoelectric layer;
wherein the first blocks each have a preferential axis of deformation parallel to the reference plane.

17. The converter as claimed in claim 16, wherein the first blocks are produced in magnetostrictive material and have magnetostriction coefficients of a same sign and the transducer layer comprises second blocks of magnetostrictive material inserted between lateral edges of the first blocks, the magnetostriction coefficients of the second blocks being of a sign opposite to the magnetostriction coefficients of the first blocks.

18. The converter as claimed in claim 16, wherein the first blocks are produced in material with shape memory and all the first blocks are uniformly distributed about an axis of rotation at right angles to the reference plane and their preferential axes of deformation intersect on the axis of rotation.

19. The converter as claimed in claim 16, further comprising a second piezoelectric layer symmetrical to the first piezoelectric layer relative to a plane of symmetry parallel to the reference plane, this plane of symmetry being situated at mid-height of the transducer layer.

20. The converter as claimed in claim 16, wherein each first block has, in a plane parallel to the reference plane, a form factor greater than two.

21. The converter as claimed in claim 16, wherein the preferential axes of deformation are distributed along at least two different directions of the reference plane.

22. The converter as claimed in claim 16, wherein all the first blocks are uniformly distributed about an axis of rotation at right angles to the reference plane or all the first blocks are uniformly distributed on a translation axis parallel to the reference plane.

23. The converter as claimed in claim 16, wherein at least one of the first blocks comprises a lattice of wires parallel to the reference plane, the wires of this lattice being produced in magnetostrictive material or in material with shape memory.

24. An electricity generator comprising:
a converter of a variation of energy to be harvested into a potential difference between two electric terminals, the variation of energy to be harvested being a variation of magnetic field or of temperature; and
a set of a number of first sources of energy to be harvested fixed to one another with no degree of freedom, each first source locally generating energy to be harvested;
wherein the converter conforms to claim 16; and
wherein at least one of the set and of the converter can be displaced alternately, within the reference plane, between:
a first position in which the first blocks are each arranged facing a first respective source of energy to be harvested, and
a second position in which the regions are each arranged facing a first respective source and each first block is situated mid-way between two first sources.

25. The generator as claimed in claim 24, wherein:
the first blocks are produced in magnetostrictive material and have magnetostriction coefficients of a same sign,
the first sources are sources of magnetic field fixed to one another with no degree of freedom, each first source being configured, in the first position, to generate, within the first block facing, field lines parallel to the reference plane and to the preferential axis of deformation of this first block.

26. The generator as claimed in claim 25, wherein the set further comprises second sources of magnetic field, inserted between the first sources, these second sources facing a first respective block in the second position, each second source being configured, in the second position, to generate, within the first block, facing field lines parallel to the reference plane and at right angles, to within plus or minus 10°, to the preferential axis of deformation of this first block.

27. The generator as claimed in claim 25, wherein the transducer layer comprises second blocks of magnetostrictive material inserted between lateral edges of the first blocks, each second block being situated, in the second position, facing a first respective source of magnetic field, the magnetostriction coefficients of the second blocks being of a sign opposite the magnetostriction coefficients of the first blocks.

28. The generator as claimed in claim 24, wherein:
the first blocks are produced in material with shape memory,
the first sources are sources of heat fixed to one another with no degree of freedom, each first source being configured, in the first position, to heat the first block facing more than the regions situated on either side of this first block.

29. The generator as claimed in claim 24, wherein the set of sources can be displaced in rotation, relative to the converter, about an axis of rotation at right angles to the reference plane to pass between the first and second positions, and the first sources are uniformly distributed about the axis of rotation.

30. The generator as claimed in claim 24, wherein the set of sources can be displaced in translation, relative to the converter, along an axis of translation parallel to the reference plane to pass between the first and second positions, and the first sources are uniformly distributed along this axis of translation.
